(19) United States
(12) Patent Application Publication
(10) Pub. No.: US 2011/0090171 A1
(43) Pub. Date: Apr. 21, 2011

(54) Integrated Substrate and Display with Electromagnetic Sensor Loop

(75) Inventors: Wei-Chou Chen, Hsin-Chu (TW); Yun-Hsiang Yeh, Miaoli (TW); Cheng-Lu Liu, Hsin-Chu (TW)

(73) Assignee: WALTOP INTERNATIONAL CORPORATION, Hsinchu (TW)

(21) Appl. No.: 12/767,685

(22) Filed: Apr. 26, 2010

(30) Foreign Application Priority Data
Oct. 16, 2009 (TW) 098135141

(51) Int. Cl. G06F 3/046; G01R 31/02

(52) U.S. Cl. 345/174; 324/72

(57) ABSTRACT

The present invention relates to an integrated substrate and display with electromagnetic sensor loop, and particularly relates to a TFT/CF array substrate and flat display with electromagnetic sensor loop. In the present invention, electromagnetic sensor loop is formed on one substrate of a display panel for getting the integrated substrate with electromagnetic sensor loop. The integrated substrate with antenna loop has both a function of a detecting board and a function of one substrate of the display panel, for example a function of a TFT/CF array substrate. Therefore, a display panel or a display having electromagnetic inputting function can be fabricated by the integrated substrate without additional detecting board and digitizer tablet

### FIELD OF THE INVENTION

The present invention relates to an integrated substrate and display with electromagnetic sensor loop, and particularly relates to a TFT/CF array substrate and flat display with electromagnetic sensor loop.

### BACKGROUND OF THE INVENTION

With the development of the display and the tablet and the demand for a multi-functional display, a display integrated with a tablet is presented nowadays. The display not only displays words or images but also has a function of electromagnetic input for the user to write and draw on the display directly. Therefore, the display can has more functions.

Referring to FIG. 1A, it is a cross-section view diagram illustrating a conventional and common LCD display 10 now, which is integrated with a tablet module. The display 10 comprises a LCD panel 20, a backlight module 30, a tablet module 40 and a housing 50. The tablet module 40, the backlight module 30 and the LCD panel 20 are positioned in the housing 50 from bottom to top in order. The LCD panel 20 consists of a top substrate structure 22, a bottom substrate structure 28 and a liquid crystal layer 26 filled into the space between the substrate structure 22 and a bottom substrate structure 28. The top substrate structure 22 is a top substrate 21 having black matrixes 24 and color filters 23 deposed on the surface of the top substrate structure 22. The bottom substrate structure 28 is a bottom substrate 29 having thin film transistors (TFT) 27 deposed thereon. The tablet module 40 consists of a sensor board 42, a control board 46 and a connecting bus 44 for connecting the sensor board 42 and the control board 46.

Referring to FIG. 1B, it is a cross-section view diagram illustrating a conventional OLED display (or a conventional electronic paper display) 10B. The conventional OLED display (or a conventional electronic paper display) 10B comprises a display panel 20B, a tablet module 40 and a housing 50. The tablet module 40 and the display panel 20B are positioned in the housing 50 from bottom to top in order. The display panel 20B is an OLED display panel or an electronic paper display panel and the display panel 20B comprises a top substrate 21, a display layer 25 and a bottom substrate structure 28. The bottom substrate structure 28 is a TFT substrate consisting of several thin film transistors 27 and a bottom substrate 29. The tablet module 40 consists of a sensor board 42, a control board 46 and a connecting bus 44 for connecting the sensor board 42 and the control board 46.

However, no matter the above-mentioned displays 10 or 10B, which is integrated with a tablet module, is formed by attaching a sensor board or a tablet module direct to the backside of a conventional display and by assembling the sensor board (or a tablet module) and the conventional display into a housing. Both of the conventional displays 10 and 10B reflect the electromagnetic signals emitted by the sensor board by a special input device, for example a special pen, or the special pen directly emits the electromagnetic signals. After the sensor board detects the electromagnetic signals reflected or emitted by the input device, the control board processes the electromagnetic signals for judging or finding the position of the input device and the pressure exerted by the input device. Therefore, contrasting the displays 10, 10B with the conventional display without the tablet module, the displays 10, 10B integrated with the tablet module are formed by stacking the two devices (the display and the tablet module) directly, and the thickness of each of the conventional displays 10, 10B integrated with the tablet module is at least the sum of the thickness of the conventional display having the tablet module therein and the thickness of the tablet module outside the conventional display having the tablet module therein. The thickness and the size of the conventional displays integrated with the tablet module are obviously increased and are obviously larger than the thickness and the size of the conventional display without the tablet module. Therefore, the conventional display integrated with the tablet module does not match the demand for the display with the characteristics of low weight and low thickness.

Furthermore, no matter the above-mentioned displays 10 or 10B has a need of an extra sensor board so it results in the high cost and this cost can not be decreased. In general, the conventional display has a need of an external frame for protecting and fixing the display panel therein. However, the external frame often interferes with and affects the electromagnetic field at the edges of the conventional display integrated with the tablet module, and it results in that the position of the input device is easy to be detected erroneously at the edges of the conventional display integrated with the tablet module. Therefore, there is a need to provide an integrated substrate capable of being used as both of a sensor board and one substrate of the display, and to provide a display having the characteristics of small size, low thickness, low cost, having the function of electromagnetic input, and no interference in the electromagnetic field at the edges.

### SUMMARY OF THE INVENTION

One objective of this invention is to provide an integrated substrate with electromagnetic sensor loop. The integrated substrate with electromagnetic sensor loop has both of the function of a sensor board and the function of a TFT substrate (or a TFT array substrate) or a CF substrate (or a CF array substrate) of a display panel. A display having the function of electromagnetic input can be fabricated directly by this integrated substrate.

Another objective of this invention is to provide a display wherein an integrated substrate with electromagnetic sensor loop is used instead of both of a tablet and one substrate of the display panel for directly fabricating a display panel having the function of electromagnetic input. Further, this display panel can be used to fabricate a display having the function of electromagnetic input. This display has no need to be integrated with an extra sensor board or an extra tablet module. Therefore, the cost, the size and the thickness of the display are reduced, and there is no interference in the electromagnetic field at the edges caused by the external frame and this display does not detect the position of the input device erroneously at the edges.

Still another objective of this invention is to provide a method for fabricating an integrated substrate with electromagnetic sensor loop. The electromagnetic sensor loop is formed directly on one substrate of a display panel for forming an integrated substrate with electromagnetic sensor loop instead of both of the sensor board and one substrate of a display panel. Therefore, the display panel can have the function of electromagnetic input.

Still another objective of this invention is to provide a method for fabricating a display. An integrated substrate with electromagnetic sensor loop is fabricated instead of both of the sensor board and one substrate of a display panel for forming a display having the function of electromagnetic input. This display has no need of an extra sensor board or tablet module. Therefore, comparing with the conventional display integrated with a tablet module, the size, the thickness and the cost of this display are substantially decreased and there is no interference at the edges of the display caused by the external frame.

According to above-mentioned objectives, in one embodiment of the present invention, an integrated substrate with electromagnetic sensor loop is provided and a display having the function of electromagnetic input can be formed by this integrated substrate without the need of an extra sensor board. The integrated substrate comprises a substrate, at least one first electromagnetic sensor loop, a first insulation layer, and an element or an element array. The first electromagnetic sensor loop is deposed on the substrate for electromagnetic induction and electromagnetic input. The first insulation layer is deposed on the substrate and the first electromagnetic sensor loop for covering the first electromagnetic sensor loop. The element (or the element array) is deposed on the first insulation layer for optical control or driving control. Because the electromagnetic sensor loop and the element (or the element array), for example thin a film transistor (TFT) (or a TFT array) or a color filter (CF) (or a CF array), are formed directly on the integrated substrate, the integrated substrate has both of the function of a sensor board and the function of one substrate of a display panel, for example a TFT substrate (or a TFT array substrate) or a CF substrate (or a CF array substrate). Therefore, a display panel having the function of electromagnetic input can be formed directly by this integrated substrate with electromagnetic sensor loop.

According to above-mentioned objectives, in another embodiment of the present invention, a display is provided. This display has no need of an extra sensor or has no need to be integrated with a tablet module. This display comprises a display panel for displaying images. The display panel comprises a substrate, at least one first electromagnetic sensor loop, a first insulation layer, and an element or an element array. The first electromagnetic sensor loop is deposed on the substrate for electromagnetic induction and electromagnetic input. The first insulation layer is deposed on the substrate and the first electromagnetic sensor loop for covering the first electromagnetic sensor loop. The element (or the element array) is deposed on the first insulation layer for optical control or driving control. This display uses an integrated substrate with electromagnetic sensor loop instead of a sensor board and one substrate of a display panel. Therefore, the display having the function of electromagnetic input is formed directly by this display panel. Furthermore, the display has no need of an extra sensor board and has no need to be integrated with a tablet module so the cost, the size and the thickness can be reduced. Besides, because the electromagnetic sensor loop is fabricated on one substrate of the display panel, the electromagnetic field at the edges is not interfered by the external frame and the display does not detect the position of the input device at edges erroneously.

According to above-mentioned objectives, in one embodiment of the present invention, a method for fabricating an integrated substrate with electromagnetic sensor loop is provided. The method for fabricating an integrated substrate with electromagnetic sensor loop comprises following steps: First, a substrate is provided, and then, a metal layer is formed on the substrate for cover the surface of the substrate. After, the metal layer is patterned to form at least one first electromagnetic sensor loop and a first insulation layer is formed on the substrate and the first electromagnetic sensor loop to cover the first electromagnetic sensor loop, Last, an element or an element array is formed on the first insulation layer for optical control or driving control. In this method for fabricating an integrated substrate with electromagnetic sensor loop, both of the electromagnetic sensor loop and the element for optical control or driving control are formed on one substrate of a display panel for forming an integrated substrate having both of the function of a sensor board and the function of one substrate of the display. This integrated substrate is used instead of the sensor board and one substrate of the display panel. Therefore, the display panel can have both of the function of electromagnetic input and the function of one substrate of a display panel, for example a TFT/TFT array substrate or a CF/CF array substrate and a display having the function of electromagnetic input directly by this display. Accordingly the integrated substrate can be used to form a display panel or a display having the function of electromagnetic input without the need of an extra sensor board or an extra tablet module.

According to above-mentioned objectives, in another embodiment of the present invention, a method for fabricating a display is provided and this display has the function of electromagnetic input. This method for fabricating a display comprises following steps: First, an integrated substrate with electromagnetic sensor loop is provided or formed, and then, a display layer is deposed on the integrated substrate. Last, the integrated substrate with the display layer deposed thereon is positioned in a housing. In this method for fabricating a display, the electromagnetic sensor loop is fabricated directly on one substrate of a display panel for forming an integrated substrate with electromagnetic sensor loop, and a display panel having the function of electromagnetic input is formed directly by attaching the display layer to the integrated substrate. This display panel is formed without the need of an extra sensor. Therefore, when a display is assembled, it has no need to be integrated with a tablet module but the display having the function of electromagnetic input still can be gotten and formed by this way. Comparing with the conventional display integrated with a tablet module, the sensor board and the tablet module are omitted from the display fabricated by this method. Therefore, the thickness, the size and the cost of the display having the function of electromagnetic input are reduced substantially and a display having the function of electromagnetic input, which more conforms to the requirement of small size, low thickness and low cost, can be formed by this method.

Therefore, the effect achieved with the present invention is to provide an integrated substrate with electromagnetic sensor loop, a display and the fabricating methods thereof. And particularly, this invention provides a TFT array substrate with electromagnetic sensor loop, a display with electromagnetic sensor loop and the fabricating methods thereof. In this invention, the electromagnetic sensor loop is formed directly on one substrate of a display panel for forming an integrated substrate with electromagnetic sensor loop instead of the sensor board and the tablet module of the conventional display having the function of electromagnetic input. By this way, both of the display panel and the display fabricated by this integrated substrate can have the function of electromagnetic input directly without the need of an extra sensor board and an extra tablet module. Therefore, comparing with the conventional display with electromagnetic sensor loop, the thickness, the size and the cost of the display of the present invention are substantially reduced. Furthermore, because the integrated substrate with electromagnetic sensor loop is used to be one substrate of the display panel, and there is no interference in the electromagnetic field at the edges caused by the external frame. Therefore, the electromagnetic induction at edges is not affected by the external frame and the display does not detect the position of the input device erroneously at the edges.

### BRIEF DESCRIPTION OF THE DRAWINGS

FIG. 1A is a cross-section view diagram illustrating a conventional LCD display.

FIG. 1B is a cross-section view diagram illustrating a conventional OLED display (or a conventional electronic paper display).

FIG. 2 is a cross-section view diagram illustrating an integrated substrate with electromagnetic sensor loop in accordance with one embodiment of the present invention.

FIGS. 3A and 3B are a cross-section view diagram and a plane view diagram illustrating an integrated substrate with electromagnetic sensor loop and the electromagnetic sensor loop thereon in accordance with one embodiment of the present invention.

FIGS. 4A and 4E are cross-section view diagrams and plane view diagrams illustrating the process for fabricating the integrated substrate showed in FIG. 3A.

FIG. 5 is a plane view diagram illustrating the layout for the electromagnetic sensor loop in the integrated substrate with electromagnetic sensor loop in accordance with another embodiment of the present invention.

FIGS. 6A and 6C are cross-section view diagrams illustrating the process for fabricating the integrated substrate showed in FIG. 5.

FIGS. 7A and 7B are a cross-section view diagram and a plane view diagram respectively illustrating an integrated substrate with interlaced electromagnetic sensor loop in accordance with still another embodiment of the present invention.

FIGS. 8A and 8F are cross-section view diagrams and plane view diagrams illustrating the process for fabricating the integrated substrate showed in FIGS. 7A and 7B.

FIG. 9 is a plane view diagram illustrating an interlaced electromagnetic sensor loops distributed in Y-directions of two-dimensional Cartesian coordinates on an integrated substrate with interlaced electromagnetic sensor loops distributed in both of two directions of two-dimensional Cartesian coordinates in accordance with still another embodiment of the present invention.

FIGS. 10A and 10B are cross-section view diagrams illustrating the process for fabricating the integrated substrate with interlaced electromagnetic sensor loops distributed in both of two directions of two-dimensional Cartesian coordinates.

FIG. 11A is a cross-section view diagram illustrating a CF substrate with non-interlaced electromagnetic sensor loop in accordance with one embodiment of the present invention.

FIG. 11B is a cross-section view diagram illustrating a CF substrate with interlaced electromagnetic sensor loop in accordance with another embodiment of the present invention.

FIG. 12A is a cross-section view diagram illustrating a LCD display having the function of electromagnetic input in accordance with one embodiment of the present invention.

FIG. 12B is a cross-section view diagram illustrating a LCD display having the function of electromagnetic input in accordance with another embodiment of the present invention.

FIG. 13 is a cross-section view diagram illustrating a OLED/EPD display having the function of electromagnetic input in accordance with one embodiment of the present invention.

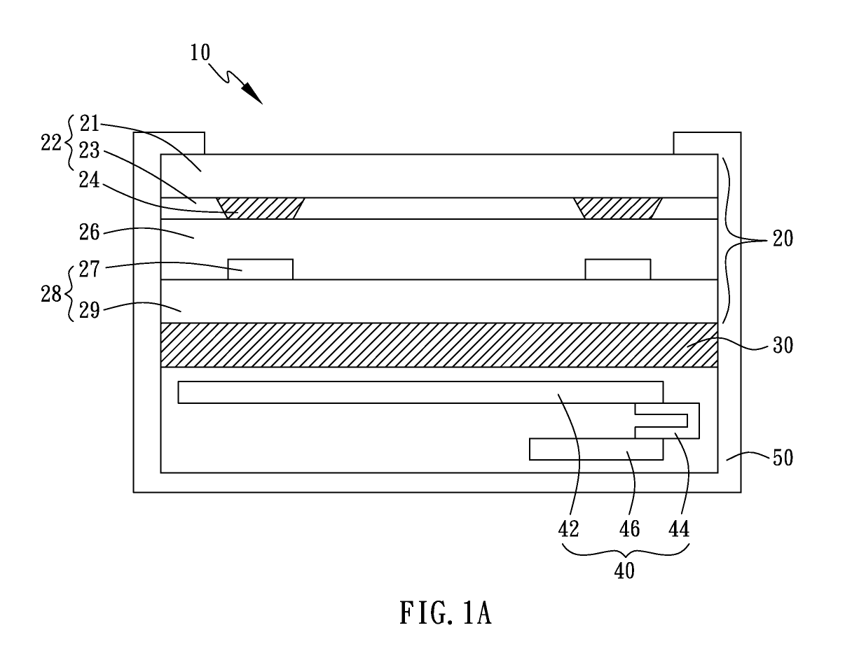

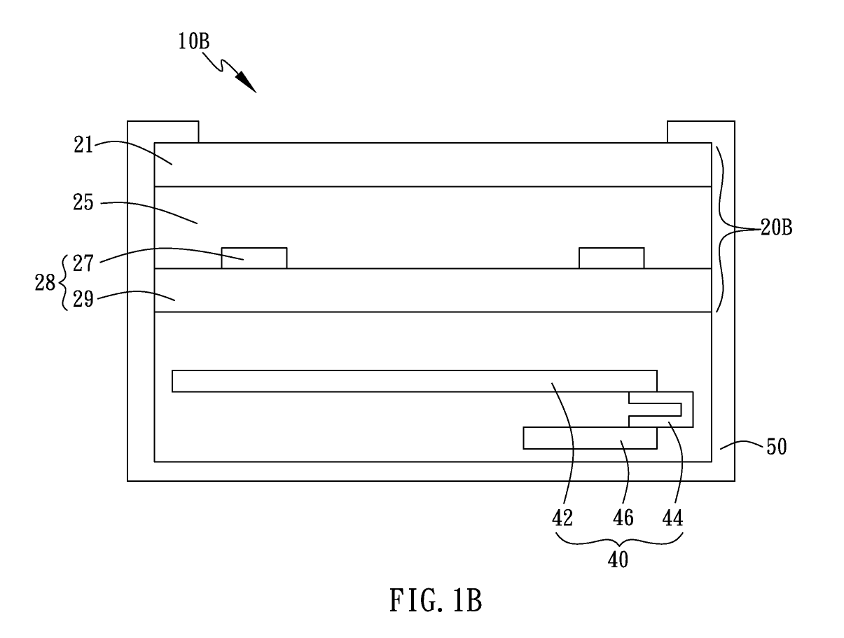

### DESCRIPTION OF THE EXEMPLARY EMBODIMENTS

Although the present invention will be described in accordance with the embodiments shown above, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

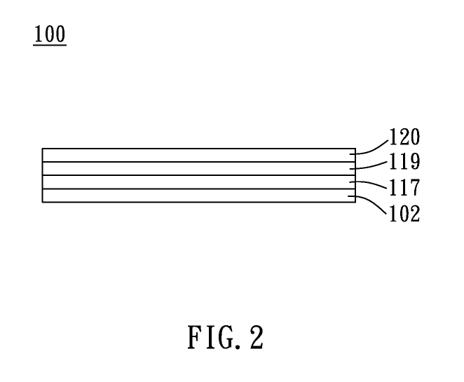

Referring to FIG. 2, it is a cross-section view diagram illustrating an integrated substrate 100 with electromagnetic sensor loop in accordance with one embodiment of the present invention. The integrated substrate 100 with electromagnetic sensor loop comprises a substrate 102, an electromagnetic sensor loop layer 117 deposed on the substrate 102, an insulation layer 119 deposed on the electromagnetic sensor loop layer 117, and an element layer 120. In the electromagnetic sensor loop layer 117, at least one electromagnetic sensor loop is fabricated directly on the substrate 102 for detecting the electromagnetic signal reflected or emitted by an input device. The element layer 120 consists of one element or several elements for optical control or driving control, for example a TFT, a TFT array, a CF, or a CF array. The integrated substrate 100 with electromagnetic sensor loop is the basic and common structure of the integrated substrates with electromagnetic sensor loop in following embodiments and the structures of the above-mentioned layers in the integrated substrate are detailed in following embodiments.

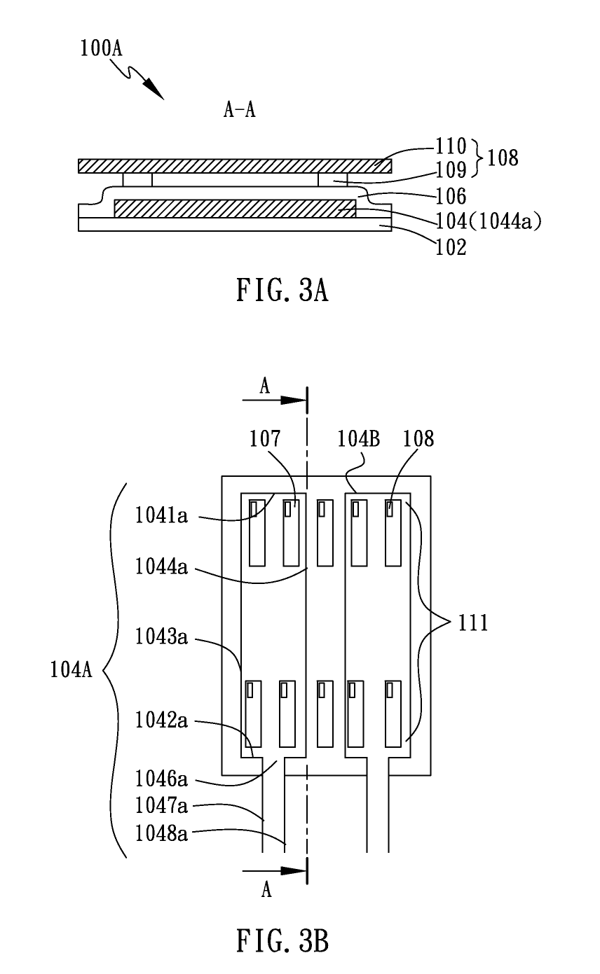

Referring to FIGS. 3A and 3B, they are a cross-section view diagram and a plane view diagram illustrating an integrated 100A substrate with electromagnetic sensor loop and the electromagnetic sensor loop thereon in accordance with one embodiment of the present invention respectively. In FIG. 3B, the thin film transistors (TFT) 108 (and the thin film transistors array (TFT array) 111) and the first electromagnetic sensor loop are drawn on the same plane for describing and showing the layout for the first electromagnetic sensor loop conveniently and clearly, but it does not mean that the TFT 108 (and the TFT array 111) and the first electromagnetic sensor loop are deposed on the same plane or layer. On the contrary, the thin film transistors 108 (the same with the element layer 120 in FIG. 2) are deposed above the first electromagnetic sensor loop 104A (the same with the electromagnetic sensor loop layer 117 in FIG. 2) as FIG. 2 illustrating. FIG. 3A is a cross-section view diagram illustrating cross-sectional structure of the integrated substrate 100A with electromagnetic sensor loop showed in FIG. 3B, which is cut along the line A-A.

This integrated substrate 100A with electromagnetic sensor loop comprises a substrate 102, several first electromagnetic sensor loops 104A, 104B deposed on the substrate 102, a first insulation layer 106 deposed on the surface of the substrate 102 and the first electromagnetic sensor loops 104A, 104B, and an TFT array 111 consisting of several thin film transistors 108 deposed on the first insulation layer 106 for optical control or driving control. Each of sub pixels has a thin film transistor 108 deposed therein for controlling the pixel to operate or work.

The first electromagnetic sensor loop 104A comprises a top side 1041a, a bottom side 1042a opposite to the top side 1041a, a first side 1043a, a second side 1044a opposite to and parallel to the first side 1043a, a first terminal 1047a and a second terminal 1048a. All of the top side 1041a, the bottom side 1042a, the first side 1043a, the second side 1044a, the first terminal 1047a and the second terminal 1048a are deposed on the substrate 102. The bottom side 1042a has an opening 1046a and the two ends of the opening 1046a are connected respectively with the first terminal 1047a and the second terminal 1048a to be the connectors of the first electromagnetic sensor loop 104A for being connected with and controlled by a control board. One end of the top side 1041a and the end of the bottom side 1042a corresponding to this end of the top side 1041a are connected with each other by the first side 1043a. Another end of the top side 1041a and another end of the bottom side 1042a which corresponds to another end of the top side 1041a are connected with each other by the second side 1044a. Therefore, the first electromagnetic sensor loop 104A is formed by this way and the area surrounds by the top side 1041a, the bottom side 1042a, the first side 1043a and the second side 1044a is the sensor area of the first electromagnetic sensor loop 104A for inducing the electromagnetic signals reflected or emitted by an input device. The first electromagnetic sensor loop 104A showed in FIG. 3A is the second side 1044a of the first electromagnetic sensor loops 104A.

The first electromagnetic sensor loop 104B has the same structure with the first electromagnetic sensor loop 104A, and each side or each area of the first electromagnetic sensor loop 104A does not interlace and overlap with any side or area of the first electromagnetic sensor loop 104B. Therefore, the first electromagnetic sensor loops 104A, 104B are the non-interlaced electromagnetic sensor loops. In this embodiment, although only two first electromagnetic sensor loops 104A, 104B are deposed on the substrate 102, but not limit. In other embodiments of this invention, there is only one first electromagnetic sensor loop deposed on the substrate or there are more first electromagnetic sensor loops deposed on the substrate.

The substrate 102 is a glass substrate or other substrate which light can pass through, and various kinds of the substrates can be adopted to be the substrate 102 according to the requirement. In this embodiment, although several thin film transistors 108 are deposed on the substrate 102 to form a TFT array 111, but in other embodiments, the thin film transistors deposed on the substrate can be increased or decreased according to the requirement and even there is only one thin film transistor deposed on the substrate. Each of the thin film transistors 108 comprises a lateral metal line 109 for being a gate line of the thin film transistors 108 and a vertical metal line 110 for being a source line of the thin film transistors 108. Both of the first electromagnetic sensor loops 104A, 104B are distributed along the lateral metal lines 109 (the gate lines) and the vertical metal lines 110 (the source lines) to be deposed under the lateral metal lines 109 (the gate line) and the vertical metal lines 110 (the source lines). Therefore, the impact on the aperture ratio of the integrated substrate 100A caused by the first electromagnetic sensor loops 104A, 104B is avoided and reduced.

Taking the first electromagnetic sensor loop 104A as an example, the first side 1043a and the second side 1044a are deposed underneath the vertical metal lines 110 (the source lines), and the top side 1041a and the bottom side 1042a are deposed underneath the lateral metal lines 109 (the gate lines). Because where the lateral metal lines 109 and vertical metal lines 110 are deposed on the opaque areas of the substrate 102 which are originally opaque, the first electromagnetic sensor loop 104A is deposed underneath the lateral metal lines 109 and vertical metal lines 110 and it means that the first electromagnetic sensor loop 104A is deposed underneath the opaque areas of the substrate 102 which are originally opaque. Therefore, the first electromagnetic sensor loop 104A does not cause the impact on the aperture ratio of the integrated substrate 100A.

The first electromagnetic sensor loops 104A, 104B and the TFT array 111 (or the thin film transistors 108) are fabricated directly on the substrate 102 to form a TFT array substrate (or a TFT substrate) with electromagnetic sensor loops. The TFT array substrate (or the TFT substrate) with electromagnetic sensor loops has both of the function of the electromagnetic input and the function of driving control. It means that the integrated substrate 100A with electromagnetic sensor loop has both of the function of the sensor board and the function of the TFT array substrate (or the TFT substrate) of the display panel. Therefore, a display panel having the function of electromagnetic input is formed directly by the integrated substrate 100A with electromagnetic sensor loop without a need of extra sensor board. Even the display panel formed by the integrated substrate 100A with electromagnetic sensor loop can be applied to form a display (or a flat display), which has had the function of electromagnetic input already, without being integrated with an extra tablet module.

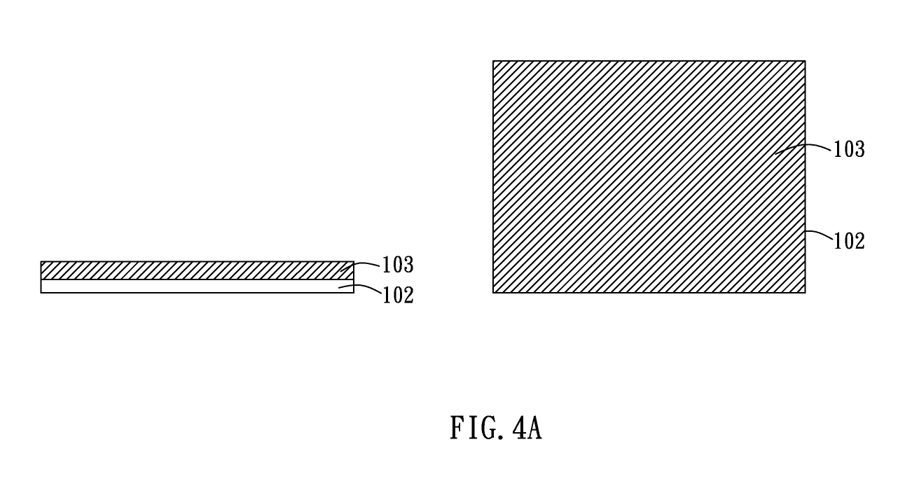

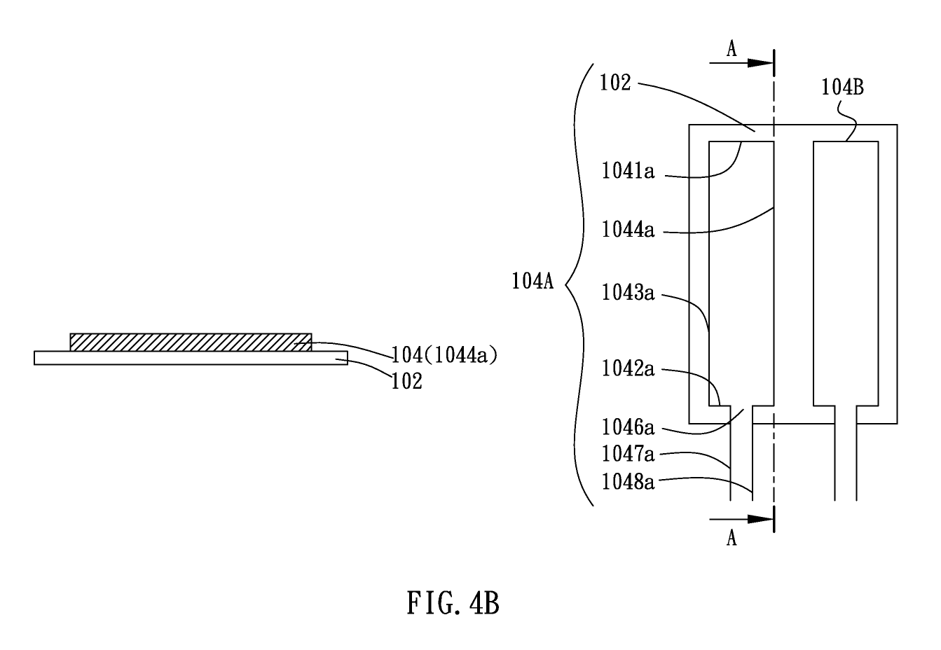

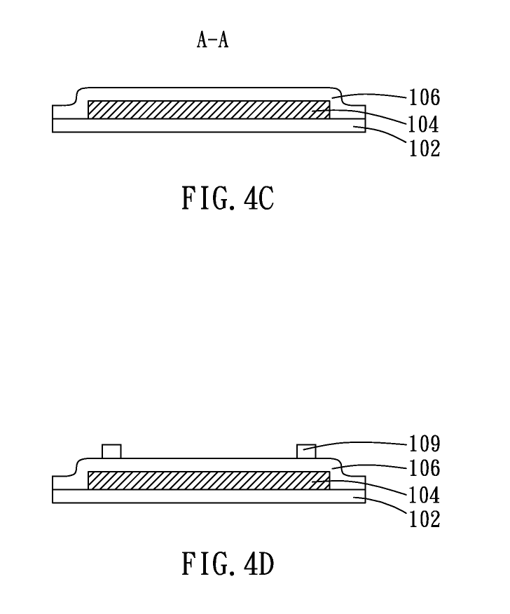

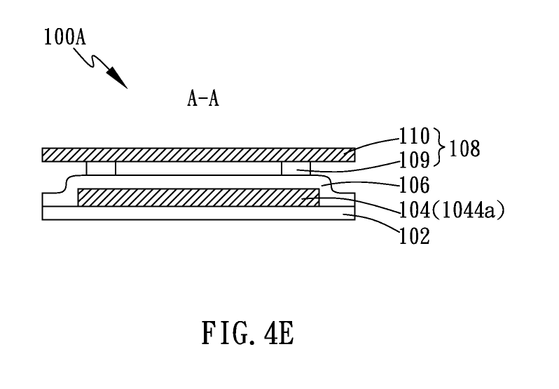

Referring to FIGS. 4A to 4E, they are cross-section view diagrams and plane view diagrams illustrating the process for fabricating the integrated substrate 100A with electromagnetic sensor loop showed in FIGS. 3A and 3B. This process and method for fabricating the integrated substrate 100A are showed a series of cross-section view diagrams and plane view diagrams. The method for fabricating the integrated substrate 100A with electromagnetic sensor loop comprises following steps: First, referring to FIG. 4B, a substrate 102 is provided and a metal layer 103 is formed on the substrate 102 for covering the surface of the substrate 102.

And then, referring to FIG. 4B, the metal layer 103 is patterned to form the first electromagnetic sensor loops 104A, 104B. The process for patterning the metal layer 103 comprises following steps: First, a photo resist is formed on the metal layer 103, and then, the photo resist is patterned to form the patterns of the top sides, the bottom sides, the first sides, the second sides, the first terminals and the second terminals of the first electromagnetic sensor loops 104A, 104B on the metal layer 103 to cover part of the metal layer 103. The other part of the metal layer 103 without these patterns is exposed from the photo resist. It means that only the part of the metal layer 103, which is predetermined area for forming the first electromagnetic sensor loops 104A, 104B, is covered by the photo resist, and the other part of the metal layer 103 is not covered by the photo resist. After, the part of the metal layer 103 which is not covered by the photo resist is removed, and then, the photo resist is removed for getting and forming the non-interlaced first electromagnetic sensor loops 104A, 104B.

Referring to FIG. 4C, a first insulation layer 106 is formed on the substrate 102 and the first electromagnetic sensor loops 104A, 104B to cover the first electromagnetic sensor loops 104A, 104B. The first insulation layer 106 is made of an insulating material such as a silicon nitride (SiNx), a silicon oxide (SiOx), a silicon oxynitride (SiNxOy) or other transparent insulating material. And then, at least one TFT 108 (or a TFT array) is fabricated on the first insulation layer 106. Referring to FIG. 4D, a lateral metal line 109 is formed on the first insulation layer 106 to be a the gate line of the TFT 108 firstly, and then, referring to FIG. 4E, a vertical metal line 110 is formed on the first insulation layer 106 to be the source line of the TFT 108. By this way, the integrated substrate 100A with electromagnetic sensor loop showed in FIGS. 3A and 3B is formed and gotten.

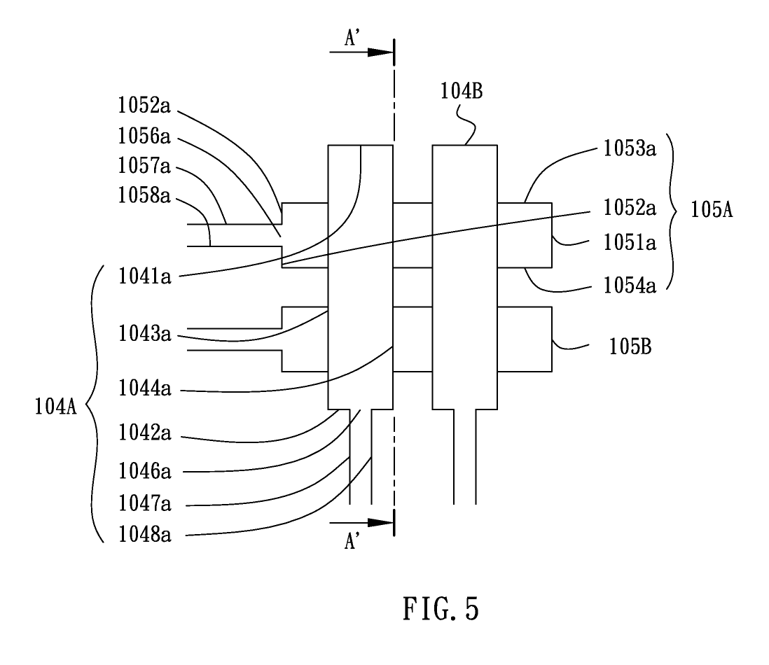

The first electromagnetic sensor loops 104A, 104B of the integrated substrate 100A showed in FIGS. 3A and 3B are distributed in one of the two directions of two-dimensional Cartesian coordinates, such as X-direction or Y-direction of two-dimensional Cartesian coordinates. However, in other embodiments of this invention, the integrated substrate can has both of the first electromagnetic sensor loops distributed in one direction of two-dimensional Cartesian coordinates and the second electromagnetic sensor loops distributed in another directions of two-dimensional Cartesian coordinates. Referring to FIG. 5, it is a plane view diagram illustrating the layout for the electromagnetic sensor loop in the integrated substrate 100′ A with electromagnetic sensor loop in accordance with another embodiment of the present invention. The layout for the electromagnetic sensor loops comprises the first electromagnetic sensor loops 104A, 104B distributed in X-direction of two-dimensional Cartesian coordinates and the second electromagnetic sensor loops 105A, 105B distributed in Y-direction of two-dimensional Cartesian coordinates. The first electromagnetic sensor loops 104A, 104B and the second electromagnetic sensor loops 105A, 105B have the same structure and all of them have a top side 1041a, 1051a, a bottom side 1042a, 1052a, a first side 1043a, 1053a, a second side 1044a, 1054a, a first terminal 1047a, 1057a, and a second terminal 1048a, 1058a.

The method for fabricating the layout for the electromagnetic sensor loops in the integrated substrate 100′A showed in FIG. 5 comprises following steps: First, referring to FIGS. 4A to 4C, the first electromagnetic sensor loops 104A, 104B are formed on the substrate 102 and a first insulation layer 106 is formed on the first electromagnetic sensor loops 104A, 104B and the substrate 102 by the steps showed in FIGS. 4A to 4C.

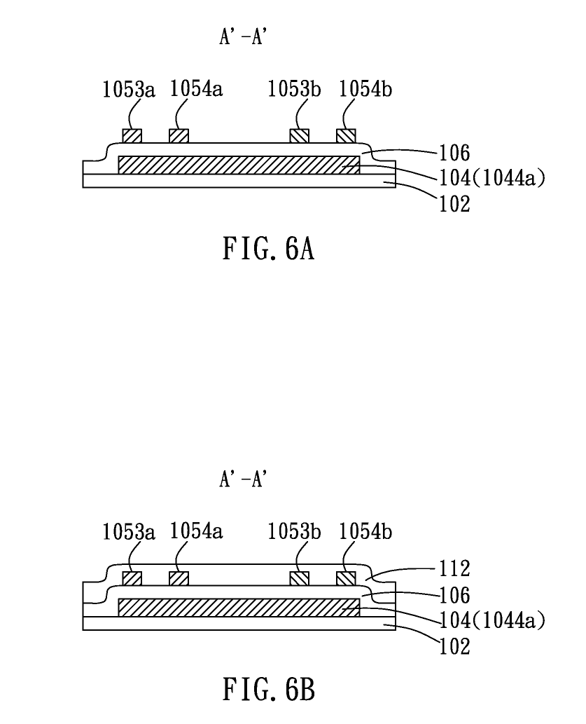

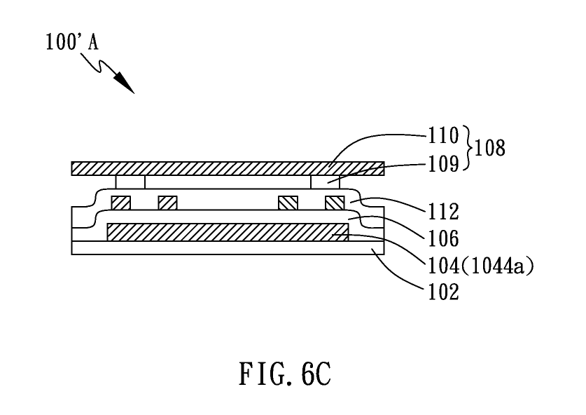

And then, Referring to FIGS. 6A to 6C, they are cross-section view diagrams illustrating the following process for fabricating the integrated substrate 100′A showed in FIG. 5. The following process is showed by a series of cross-section view diagrams step by step which are cut along the line A′-A′. Referring to FIG. 6A, first, another metal layer is formed on the first insulation layer 106, and this metal layer on the first insulation layer 106 is patterned to form the second electromagnetic sensor loops 105A, 105B on the first insulation layer 106. The first electromagnetic sensor loops 104A, 104B and the second electromagnetic sensor loops 105A, 105B are separated by the first insulation layer 106 for preventing the second electromagnetic sensor loops 105A, 105B from being contacted with the first electromagnetic sensor loops 104A, 104B. The steps for patterning the metal layer for forming the second electromagnetic sensor loops 105A, 105B are the same with the foregoing steps for patterning the metal layer 103 showed in FIG. 3B. Therefore, they are not mentioned herein again.

And then, referring to FIG. 6B, a second insulation layer 112 is formed on the first insulation layer 106 and the second electromagnetic sensor loops 105A, 105B, and the second insulation layer 112 covers the first insulation layer 106 and the second electromagnetic sensor loops 105A, 105B. The material of the substrate 102 and the material of the first insulation layer 106 are detailed before, so they are not mentioned herein again. The second insulation layer 112 can be made of the same material with the first insulation layer 106. Last, referring to FIG. 6C, a TFT array (including one thin film transistor or several thin film transistors 108) is formed on the second insulation layer 112. Each of the thin film transistors 108 in the TFT array has a gate line 109 and a source line 110. By this method, the integrated substrate 100′A with the layout for the electromagnetic sensor loops showed in FIG. 5 is formed, and the layout for the electromagnetic sensor loops includes the electromagnetic sensor loops distributed in both of the two directions of two-dimensional Cartesian coordinates. Each of the thin film transistors 108 has a gate line (the lateral metal line) 109 and a source line (the vertical metal line) 110.

The first electromagnetic sensor loops 104A, 104B in the integrated substrate 100′A have the same structure with the first electromagnetic sensor loops showed in FIG. 3A. In both of them, the top sides and the bottom sides are deposed respectively underneath gate lines (the lateral metal lines) 109, and the first sides and the second sides are deposed respectively underneath the source lines (the vertical metal lines) 110. The second electromagnetic sensor loops 105A, 105B in the integrated substrate 100′A are also deposed underneath the gate lines (the lateral metal lines) 109 and the source lines (the vertical metal lines) 110. Taking the second electromagnetic sensor loop 105A as an example, the first sides and the second sides of the second electromagnetic sensor loop 105A are deposed respectively underneath one of the gate lines (the lateral metal lines) 109, and the top sides and the bottom sides are deposed respectively underneath one of the source lines (the vertical metal lines) 110. Because both of the layout for the first electromagnetic sensor loops 104A, 104B and the layout for the second electromagnetic sensor loops 105A, 105B are distributed along the gate lines (the lateral metal lines) 109 or the source lines (the vertical metal lines) 110 which are originally designed as the opaque areas in the integrated substrate, the impact on the aperture ratio of the substrate can be avoided.

The first electromagnetic sensor loops 104A and 104B of the foregoing integrated substrates 100A, 100′A are not interlaced with each other, and the first electromagnetic sensor loops 104A does not overlay the first electromagnetic sensor loops 104B. The layout for the first electromagnetic sensor loops 104A and 104B is a layout for non-interlaced electromagnetic sensor loops. Similarly, the second electromagnetic sensor loops 105A and 105B are not interlaced with each other, and the second electromagnetic sensor loops 105A does not overlay the second electromagnetic sensor loops 105B. The layout for the second electromagnetic sensor loops 105A and 105B is also a layout for non-interlaced electromagnetic sensor loops. However, in other embodiments of this invention, the electromagnetic sensor loops in the integrated substrate can be interlaced with each other and the layout for the electromagnetic sensor loops is a layout for interlaced electromagnetic sensor loops.

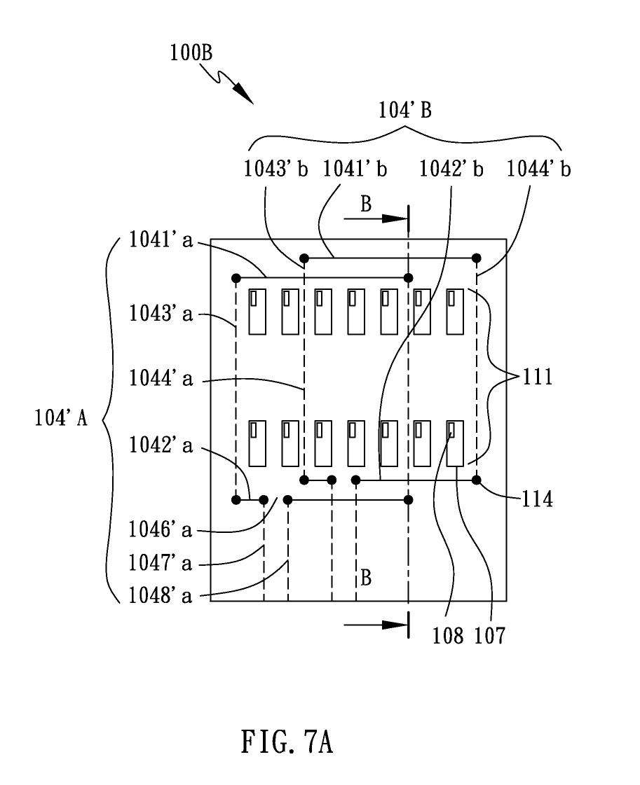

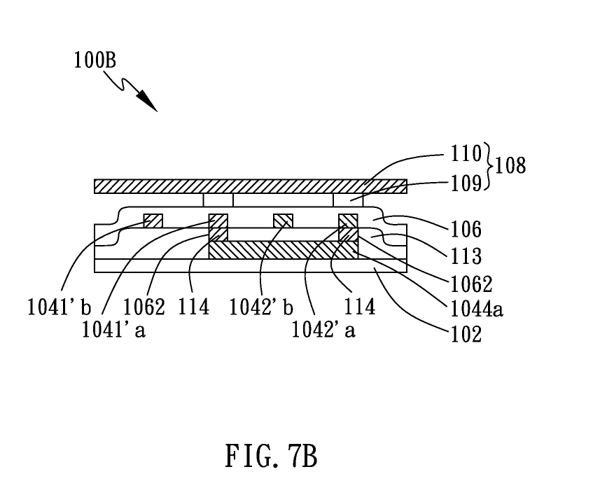

Referring to FIGS. 7A and 7B, they are a cross-section view diagram and a plane view diagram respectively illustrating an integrated substrate 100B with interlaced electromagnetic sensor loop in accordance with still another embodiment of the present invention. FIG. 7B is the cross-section view diagram illustrating the integrated substrate 100B with interlaced electromagnetic sensor loop showed in FIG. 7B which is cut along the line B-B. In FIG. 7A, the thin film transistors (TFT) 108 (and the thin film transistors array (TFT array) 111) and the first electromagnetic sensor loops 104′A, 104′B are drawn on the same plane for describing and showing the layout for the first electromagnetic sensor loops 104′A, 104′B conveniently and clearly, but it does not mean that the TFT 108 (and the TFT array 111) and the first electromagnetic sensor loops 104′A, 104′B are deposed on the same plane. On the contrary, the thin film transistors 108 (the same with the element layer 120 in FIG. 2) are deposed above the first electromagnetic sensor loops 104′A, 104′B (the same with the electromagnetic sensor loop layer 117 in FIG. 2) as FIG. 2 illustrating.

Similarly, the integrated substrate 100B with interlaced electromagnetic sensor loop comprises a substrate 102, several first electromagnetic sensor loops 104′A, 104′B deposed on the substrate 102, a first insulation layer 106 deposed on the surface of the substrate 102 and the first electromagnetic sensor loops 104′A, 104′B for covering the surface of the substrate 102 and the first electromagnetic sensor loops 104′A, 104′B, and an TFT array 111 consisting of several thin film transistors 108 deposed on the first insulation layer 106 for optical control or driving control.

As FIG. 7A shows, the first electromagnetic sensor loops 104′A and 104′B are interlaced with each other, and they have the same structure. The first electromagnetic sensor loop 104′A, 104′B comprises a top side 1041′a, 1041′b, a bottom side 1042′a, 1042′b opposite to and parallel to the top side 1041′a, 1041′b, a first side 1043′a, 1043′b, a second side 1044′a, 1044′b opposite to and parallel to the first side 1043′a, 1043′b, a first terminal 1047′a, 1047′b and a second terminal 1048′a, 1048′b. The bottom side 1042′a, 1042′b has an opening 1046′a, 1046′b and the two ends of the opening 1046′a, 1046′b are connected respectively with the first terminal 1047′a, 1047′b and the second terminal 1048′a, 1048′b to be the connectors of the first electromagnetic sensor loop 104′A, 104′B for being connected with and controlled by a control board. One end of the top side 1041′a, 1041′b and the end of the bottom side 1042′a, 1042′b corresponding to this end of the top side 1041′a, 1041′b are connected with each other by the first side 1043′a, 1043′b. Another end of the top side 1041′a, 1041′b and another end of the bottom side 1042′a, 1042′b which corresponds to another end of the top side 1041′a, 1041′b are connected with each other by the second side 1044′a, 1044′b. Therefore, the first electromagnetic sensor loop 104′A, 104′B is formed by this way.

Referring FIGS. 7A and 7B, only the first side 1043′a, 1043′b, the second side 1044′a, 1044′b, the first terminal 1047′a, 1047′b and the second terminal 1048′a, 1048′b are formed directly on the surface of the substrate 102. A first protective layer 113 is deposed on the substrate 103 for covering the surface of the substrate 102 and the first side 1043′a, 1043′b, the second side 1044′a, 1044′b, the first terminal 1047′a, 1047′b and the second terminal 1048′a, 1048′b deposed on the surface of the substrate 102. Several through holes 1062 are deposed in the first protective layer 113. The through holes 1062 are deposed respectively at the places in the first protective layer 113 which respectively correspond to two ends of the first side 1043′a, 1043′b, two ends of the second side 1044′a, 1044′b, one end of the first terminal 1047′a, 1047′b predetermined to be connected with the bottom side 1042′a, 1042′b, and one end of the second terminal 1048′a, 1048′b predetermined to be connected with the bottom side 1042′a, 1042′b. Each of the through holes 1062 passes through the first protective layer 113, and a metal is filled into the through holes 1062 for forming conductors 114 passing through the first protective layer 113. The conductors 114 are contacted and electrically connected respectively with the two ends of the first side 1043′a, 1043′b, the two ends of the second side 1044′a, 1044′b, the end of the first terminal 1047′a, 1047′b predetermined to be connected with the bottom side 1042′a, 1042′b, and the end of the second terminal 1048′a, 1048′b predetermined to be connected with the bottom side 1042′a, 1042′b.

Besides, the top side 1041′a, 1041′b and the bottom side 1042′a, 1042′b of the first electromagnetic sensor loops 104′A and 104′B are deposed on the first protective layer 113. The two ends of the top side 1041′a, 1041′b are contacted and electrically connected respectively with the ends of conductors 114 which are exposed from the first protective layer 113, and the two ends of the bottom side 1042′a, 1042′b are contacted and electrically connected respectively with the ends of conductors 114 which are exposed from the first protective layer 113. Both of the top side 1041′a, 1041′b and the bottom side 1042′a, 1042′b are connected (or electrically connected) respectively with the two ends of the first side 1043′a, 1043′b, the two ends of the second side 1044′a, 1044′b, one end of the first terminal 1047′a, 1047′b, and one end of the second terminal 1048′a, 1048′b for forming the first electromagnetic sensor loops 104′A, 104′B which are interlaced with each other. Both of the top side 1041′a, 1041′b and the bottom side 1042′a, 1042′b are deposed in lateral direction, and the first side 1043′a, 1043′b, the second side 1044′a, 1044′b, the first terminal 1047′a, 1047′b and the second terminal 1048′a, 1048′b are deposed in vertical direction. Because the lateral top side 1041′a, 1041′b, the lateral bottom side 1042′a, 1042′b, the vertical first side 1043′a, 1043′b, the vertical second side 1044′a, 1044′b, the vertical first terminal 1047′a, 1047′b and the vertical second terminal 1048′a, 1048′b are deposed on different layers of the integrated substrate 100B. Therefore, although the first electromagnetic sensor loops 104′A and 104′B seem to be interlaced with each other but they are not contacted with each other. Furthermore, they do not interfere with each other and they won't become short circuits.

Similarly, both of the first electromagnetic sensor loops 104′A and 104′B are distributed along the gate lines (the lateral metal lines) 109 or the source lines (the vertical metal lines) 110 of the thin film transistors 108 on the substrate 102, and they are deposed underneath the gate lines (the lateral metal lines) 109 or the source lines (the vertical metal lines) 110. Therefore, the impact on the aperture ratio of the integrated substrate 100B caused by the first electromagnetic sensor loops 104′A and 104′B is little. Taking the first electromagnetic sensor loop 104′A as an example, the first side 1043′a and the second side 1044′a are deposed underneath the source lines (the vertical metal lines) 110, and the top side 1041′a and the bottom side 1042′a are deposed underneath the gate lines (the lateral metal lines) 109.

In this embodiment, the first side 1043′a, 1043′b, the second side 1044′a, 1044′b, the first terminal 1047′a, 1047′b and the second terminal 1048′a, 1048′b are deposed directly on the surface of the substrate 102 first, and then, the top side 1041′a, 1041′b and the bottom side 1042′a, 1042′b are deposed on the first protective layer 113. However, in other embodiment of this invention, the top side 1041′a, 1041′b and the bottom side 1042′a, 1042′b are deposed directly on the surface of the substrate 102 first, and then, the first side 1043′a, 1043′b, the second side 1044′a, 1044′b, the first terminal 1047′a, 1047′b and the second terminal 1048′a, 1048′b are deposed on the first protective layer 113. The materials of the substrate 102 and the first insulation layer 106 are detailed before, and they are not mentioned herein again. The first protective layer 113 can be made of the same material which the first insulation layer 106 is made of.

In the integrated substrate 100B, the first electromagnetic sensor loops 104′A, 104′B and the TFT array 111 (or the thin film transistors 108) are fabricated directly on the substrate 102 to form a TFT array substrate (or a TFT substrate) with electromagnetic sensor loops. Therefore, the TFT array substrate (or the TFT substrate) with electromagnetic sensor loops has both of the function of the electromagnetic input and the function of driving control. It means that the integrated substrate 100B with electromagnetic sensor loop has both of the function of the sensor board and the function of the TFT array substrate (or the TFT substrate) of the display panel. Therefore, a display panel having the function of electromagnetic input is formed directly by the integrated substrate 100B with electromagnetic sensor loop without a need of extra sensor board. Even the display panel formed by the integrated substrate 100 B with electromagnetic sensor loop can be applied to form a display (or a flat display) which has had the function of electromagnetic input already without being integrated with an extra tablet module.

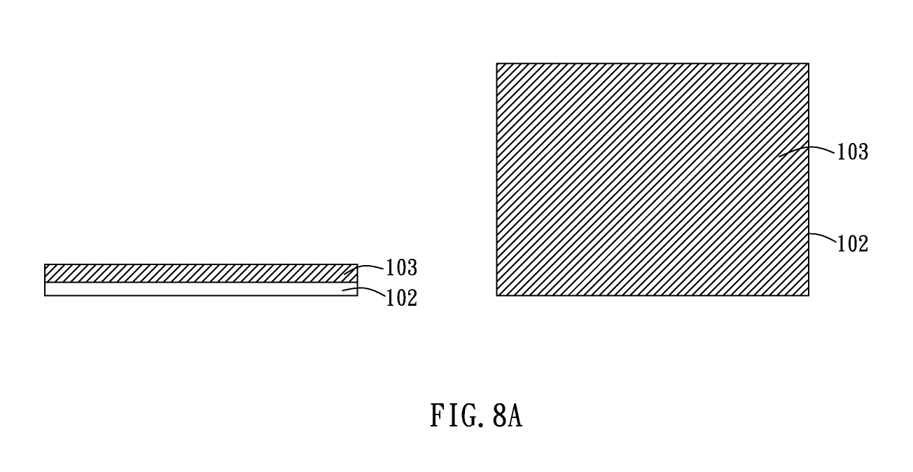

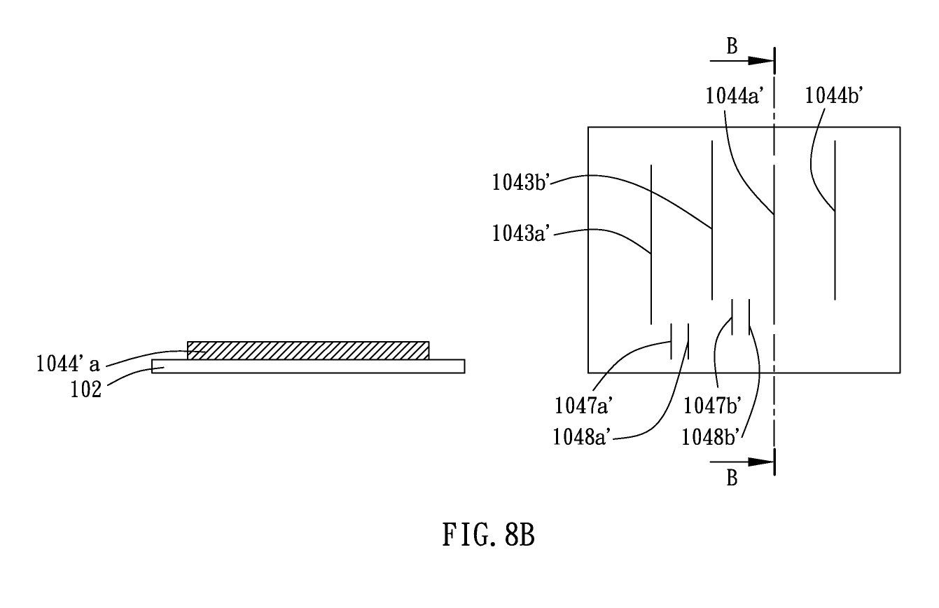

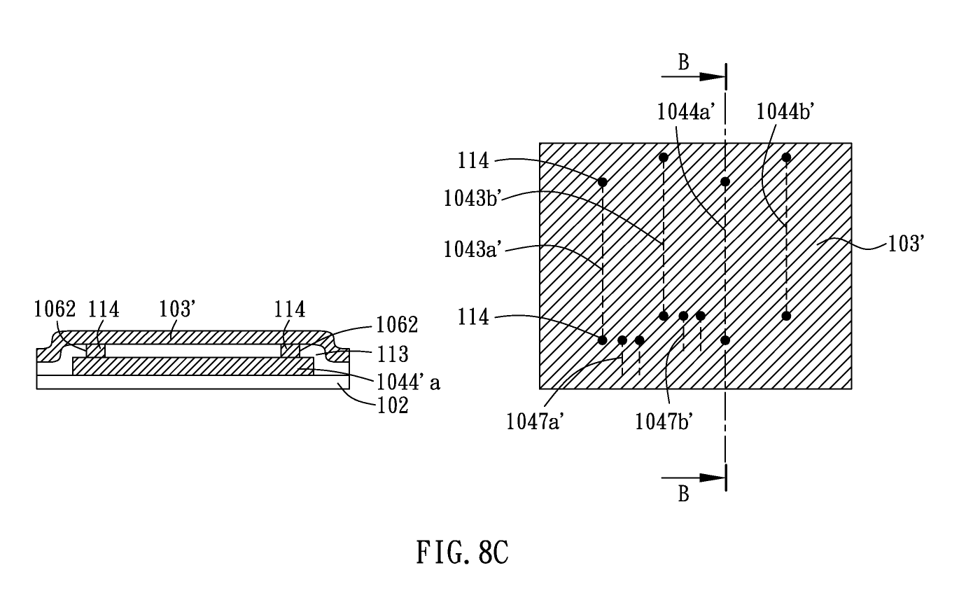

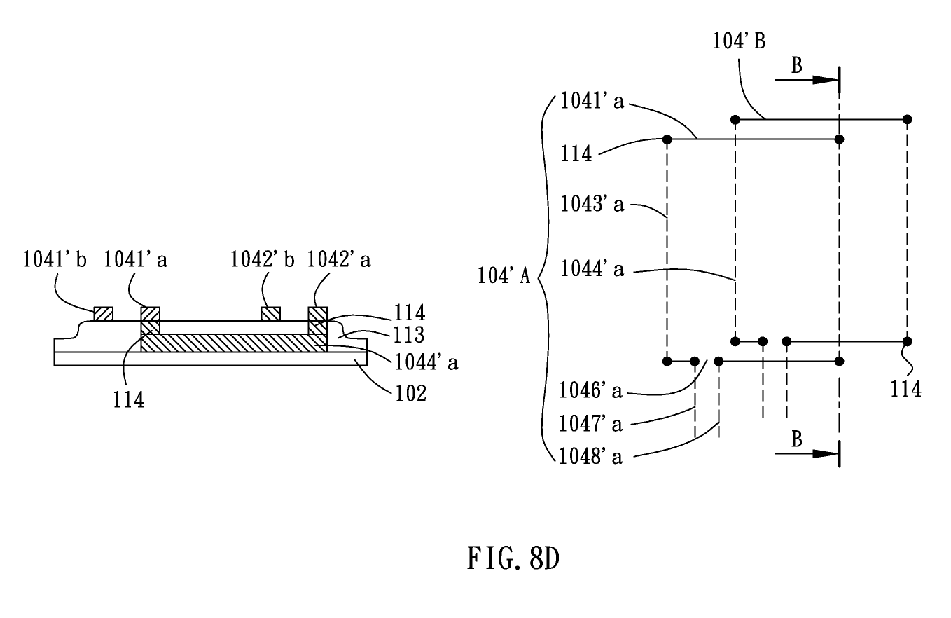

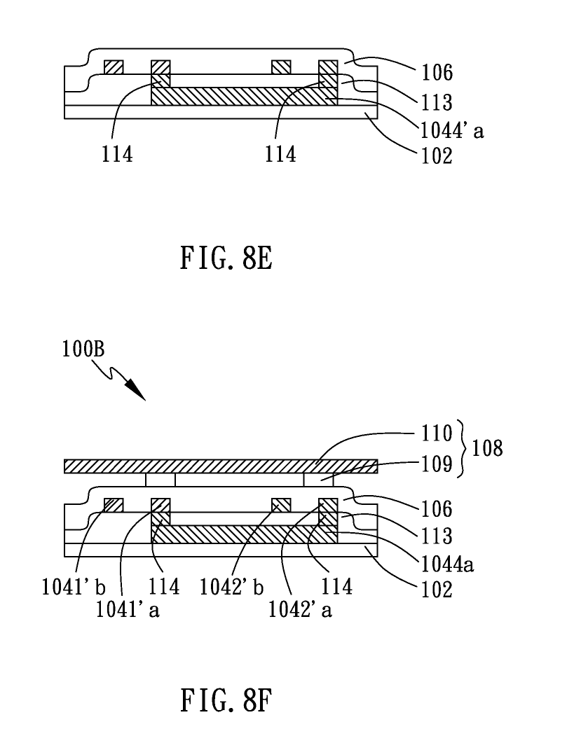

Referring to FIGS. 8A to 8F, they are cross-section view diagrams and plane view diagrams illustrating the process and method for fabricating the integrated substrate 100B with interlaced electromagnetic sensor loop showed in FIGS. 7A and 7B. The process and the method are showed by a series of cross-section view diagrams and plane view diagrams step by step. The method for fabricating the integrated substrate 100B with electromagnetic sensor loop comprises following steps: First, referring to FIG. 8A, a substrate 102 is provided, and a metal layer 103 is formed on the substrate 102 for covering the surface of the substrate 102.

And then, referring to FIG. 8B, the metal layer 103 is patterned to form the first side 1043′a, 1043′b, the second side 1044′a, 1044′b, the first terminal 1047′a, 1047′b and the second terminal 1048′a, 1048′b of the first electromagnetic sensor loops 104′A, 104′B. The process for patterning the metal layer 103 comprises following steps: First, a photo resist is formed on the metal layer 103, and then, the photo resist is patterned to form the patterns of the first side 1043′a, 1043′b, the second side 1044′a, 1044′b, the first terminal 1047′a, 1047′b and the second terminal 1048′a, 1048′b of the first electromagnetic sensor loops 104′A, 104′B on the metal layer 103 to cover part of the metal layer 103. The other part of the metal layer 103 without these patterns is exposed from the photo resist. It means that only the part of the metal layer 103, which is predetermined area for forming the first side 1043′a, 1043′b, the second side 1044′a, 1044′b, the first terminal 1047′a, 1047′b and the second terminal 1048′a, 1048′b of the first electromagnetic sensor loops 104′A, 104′B, is covered by the photo resist, and the other part of the metal layer 103 is not covered by the photo resist. After, the part of the metal layer 103 which is not covered by the photo resist is removed, and then, the photo resist is removed to get the first side 1043′a, 1043′b, the second side 1044′a, 1044′b, the first terminal 1047′a, 1047′b and the second terminal 1048′a, 1048′b of the first electromagnetic sensor loops 104′A, 104′B.

After, referring to FIG. 8C, a first protective layer 113 is formed on the substrate 102 to cover the first side 1043′a, 1043′b, the second side 1044′a, 1044′b, the first terminal 1047′a, 1047′b and the second terminal 1048′a, 1048′b. And then, several through holes 1062 are formed to pass through the first protective layer 113. The through holes 1062 are deposed respectively at the places in the first protective layer 113 which respectively correspond to two ends of the first side 1043′a, 1043′b, two ends of the second side 1044′a, 1044′b, one end of the first terminal 1047′a, 1047′b predetermined to be connected with the bottom side 1042′a, 1042′b, and one end of the second terminal 1048′a, 1048′b predetermined to be connected with the bottom side 1042′a, 1042′b. After, a second metal layer 103′ is formed on the first protective layer 113, and the second metal layer 103′ is filled into the through holes 1062 for forming a conductor 114 in each of the through holes 1062.

After, referring to FIG. 8D, the second metal layer 103′ is patterned to form the top side 1041′a, 1041′b and the bottom side 1042′a, 1042′b of the first electromagnetic sensor loops 104′A, 104′B on the first protective layer 113. The process for patterning the second metal layer 103′ comprises following steps: First, a photo resist is formed on the second metal layer 103′, and then, the photo resist is patterned to form the patterns of the top side 1041′a, 1041′b and the bottom side 1042′a, 1042′b of the first electromagnetic sensor loops 104′A, 104′B on the second metal layer 103′ to cover part of the second metal layer 103′. The other part of the second metal layer 103′ without these patterns is exposed from the photo resist. It means that only the part of the second metal layer 103′, which is predetermined area for forming the top side 1041′a, 1041′b and the bottom side 1042′a, 1042′b of the first electromagnetic sensor loops 104′A, 104′B, is covered by the photo resist and the other part of the second metal layer 103′ is not covered by the photo resist. After, the part of the second metal layer 103′ which is not covered by the photo resist is removed, and then, the photo resist is removed to get or form the top side 1041′a, 1041′b and the bottom side 1042′a, 1042′b of the first electromagnetic sensor loops 104′A, 104′B. The two ends of the top side 1041′a, 1041′b are connected respectively with the first side 1043′a, 1043′b and the second side 1044′a, 1044′b by conductors 114, and the bottom side 1042′a, 1042′b are connected respectively with the first side 1043′a, 1043′b, the second side 1044′a, 1044′b, the first terminal 1047′a, 1047′b and the second terminal 1048′a, 1048′b by conductors 114. The interlaced first electromagnetic sensor loops 104′A, 104′B are formed by this way.

And then, referring to FIG. 8E, a first insulation layer 106 is formed on the substrate 102 and the first protective layer 113 to cover the first protective layer 113 and the top side 1041′a, 1041′b and the bottom side 1042′a, 1042′b deposed on the first protective layer 113. Finally, referring to FIG. 8F, at least one TFT 108 (or a TFT array) is formed on the first insulation layer 106. Therefore, the integrated substrate 100B with electromagnetic sensor loop showed in FIGS. 7A and 7B is formed by this way.

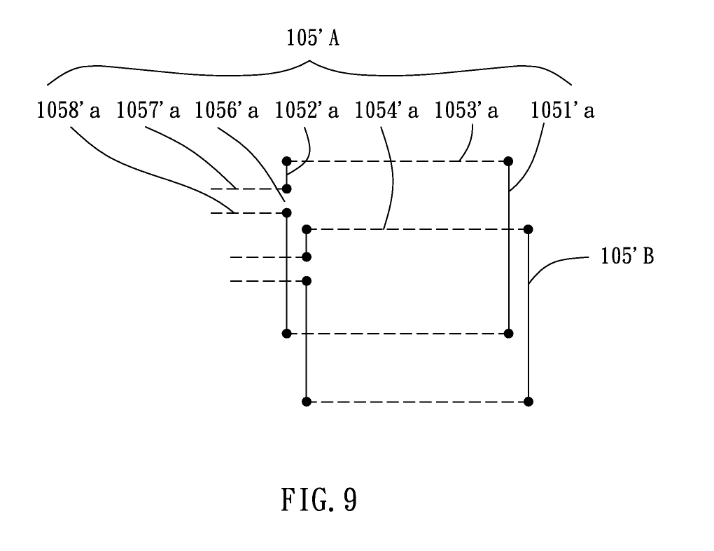

The first electromagnetic sensor loops 104′A, 104′B of the integrated substrate 100B showed in FIGS. 7A and 7B are distributed in one of the two directions of two-dimensional Cartesian coordinates, such as X-direction of two-dimensional Cartesian coordinates. However, in other embodiments of this invention, the integrated substrate has both of the interlaced first electromagnetic sensor loops distributed in one of the two directions of two-dimensional Cartesian coordinates and the interlaced second electromagnetic sensor loops distributed in another of the two directions of two-dimensional Cartesian coordinates. Referring to FIG. 9, it is a plane view diagram illustrating an interlaced electromagnetic sensor loops distributed in Y-directions of two-dimensional Cartesian coordinates on the integrated substrate 100′B with interlaced electromagnetic sensor loops distributed in both of two directions of two-dimensional Cartesian coordinates in accordance with still another embodiment of the present invention. In the integrated substrate has both of the interlaced first electromagnetic sensor loops and the interlaced second electromagnetic sensor loops, the layout for the electromagnetic sensor loops distributed in X-directions of two-dimensional Cartesian coordinates is the same with the layout for the first electromagnetic sensor loops 104′A, 104′B showed in FIG. 7A, and the layout for the electromagnetic sensor loops distributed in Y-directions of two-dimensional Cartesian coordinates is the same with the layout for the second electromagnetic sensor loops 105′A, 105′B showed in FIG. 9. The first electromagnetic sensor loops 104′A, 104′B and the second electromagnetic sensor loops 105′A, 105′B have the same structure, but the first electromagnetic sensor loops 104′A, 104′B and the second electromagnetic sensor loops 105′A, 105′B are distributed in different directions of two-dimensional Cartesian coordinates.

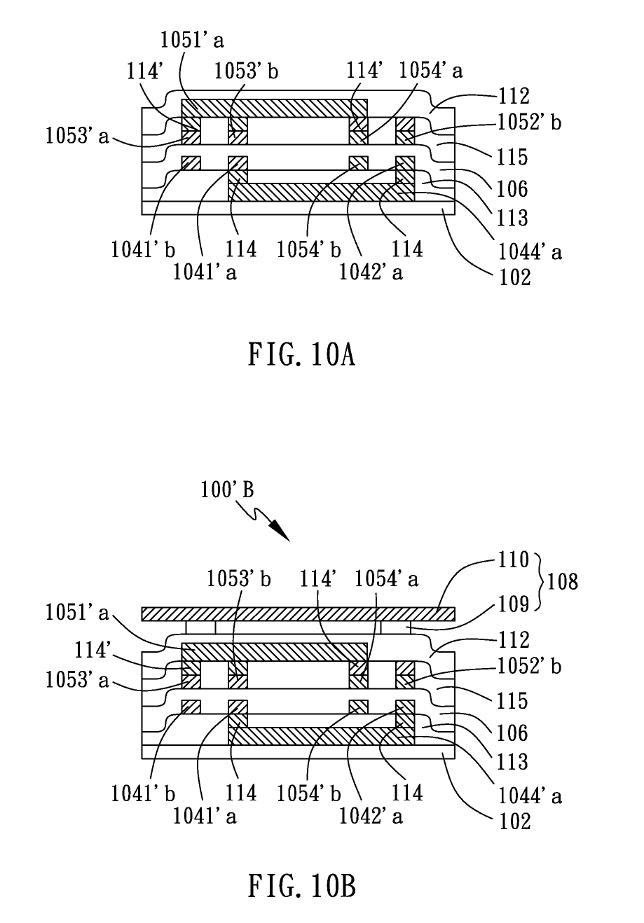

Referring to FIGS. 8A to 8E and FIGS. 10A to 10B, they are the cross-section view diagrams and plane view diagrams illustrating the process and method for fabricating the integrated substrate 100′B with interlaced electromagnetic sensor loops distributed in both of two directions of two-dimensional Cartesian coordinates. The process and the method are showed by a series of cross-section view diagrams and plane view diagrams step by step.

The method for fabricating integrated substrate 100′B with interlaced electromagnetic sensor loops comprises following steps: First, referring to FIG. 10A, the first electromagnetic sensor loops 104′A and 104′B which are interlaced with each other are formed on the substrate 102 and a first insulation layer 106 is formed on the first electromagnetic sensor loops 104′A and 104′B and the substrate 102 by repeating the above-mentioned steps showed in FIGS. 8A to 8E.

And then, referring to FIGS. 10A to 10B, they are cross-section view diagrams illustrating the following process for fabricating the integrated substrate 100′B. Referring to FIG. 10A, by repeating the above-mentioned steps showed in FIGS. 8A to 8E, another metal layer is formed on the first insulation layer 106 first, and then, the metal layer deposed on the first insulation layer 106 is patterned to form the first side 1053′a 1053′b, the second side 1054′a, 1054′b, the first terminal 1057′a, 1057′b, and the second terminal 1058′a, 1058′b of the second electromagnetic sensor loop 105′A, 105′B. And then, a second protective layer 115 is formed on the first insulation layer 106 to cover the first insulation layer 106 and the first side 1053′a 1053b, the second side 1054′a, 1054′b, the first terminal 1057′a, 1057′b, and the second terminal 1058′a, 1058′b deposed on the first insulation layer 106. After, conductors 114′ passing through the second protective layer 115 are formed in the second protective layer 115, and the top side 1051′a, 1051′b and the bottom side 1052′a, 1052′b of the second electromagnetic sensor loop 105′A, 105′B are formed on the second protective layer 115. After, a second insulation layer 112 is formed on the second protective layer 115 to cover the second protective layer 115 and the top side 1051′a, 1051′b and the bottom side 1052′a, 1052′b deposed on the second protective layer 115. The steps for patterning the metal layer to form the second electromagnetic sensor loop 105′A, 105′B are the same with the above-mentioned steps and the steps showed in FIGS. 8B to 8D, so they are not mentioned herein again. The materials of the substrate 102, the first insulation layer 106 and the first protective layer 113 are detailed before, so they are not mentioned herein again. The second protective layer 115 can be made of the same material which the first protective layer 113 is made of. Finally, referring to FIG. 10B, the thin film transistors 108 are formed on the second insulation layer 112. Therefore, the integrated substrate 100′B with interlaced electromagnetic sensor loops distributed in both of two directions of two-dimensional Cartesian coordinates can be gotten and formed by this method.

However, no matter in which above-mentioned integrated substrates 100A, 100′A, 100′B and 100′B with electromagnetic sensor loops, the electromagnetic sensor loop in the highest layer is better formed to be perpendicular to the gate lines 109. The electromagnetic sensor loop in the highest layer is the electromagnetic sensor loop which is closest to the thin film transistors 108. By this way, the interference between the electromagnetic sensor loops and the gate lines is avoided and reduced.

In the above-mentioned integrated substrates 100A, 100′A, 100′B and 100′B with electromagnetic sensor loops, the elements (or the element array) are the thin film transistors (or the TFT array). Therefore, the above-mentioned integrated substrates 100A, 100′A, 100′B and 100′B can have both the function of a sensor board and the function of the TFT substrate (or the TFT array substrate) of a display panel, and all of them are fabricated to be TFT substrates (or the TFT array substrates) having the electromagnetic sensor loops and the function of electromagnetic input. However, in other embodiments of this invention, the elements (or the element array) of the integrated substrate with electromagnetic sensor loop can be other elements (or other element array) for optical control, for example a color filter (CF) or a color filter array (CF array).

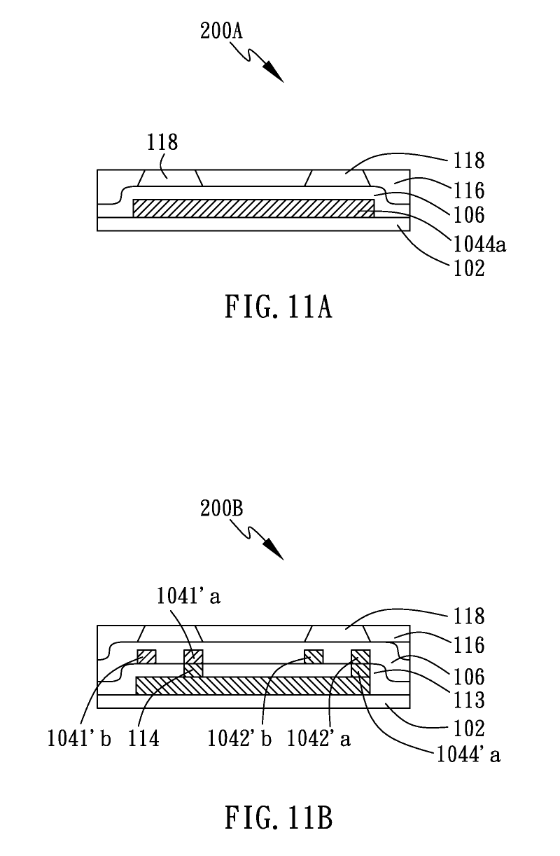

Referring to FIG. 11A, it is a cross-section view diagram illustrating an integrated substrate 200A with non-interlaced electromagnetic sensor loop in accordance with one embodiment of the present invention. The integrated substrate 200A is a CF substrate (or a CF array substrate). The integrated substrate 200A and the integrated substrate 100A with electromagnetic sensor loop showed in FIGS. 3A and 3B have similar structure. The differences between the integrated substrate 200A and the integrated substrate 100A are that in the integrated substrate 200A, a color filter (CF) (or a color filter array (CF array)) 116 is deposed on the first insulation layer 106 and several black matrixes 118 are deposed in the CF (or a F array) 116. Furthermore, the first electromagnetic sensor loop 104A is distributed along black matrixes 118 and deposed underneath the black matrixes 118. Therefore, the impact on the aperture ratio of the integrated substrate 200A is little.

The method for fabricating the integrated substrate 200A is similar to the method for fabricating the integrated substrate 100A. In the method for fabricating the integrated substrate 200A, the first electromagnetic sensor loop 104A as showed in FIG. 4C is fabricated and distributed on the substrate 102 by the above-mentioned method for fabricating the integrated substrate 100A. And then, the black matrixes 118 and the CF (or the CF array) 116 are formed on the first insulation layer 106. Therefore, a CF substrate (or a CF array substrate) with non-interlaced electromagnetic sensor loop is formed and gotten by this method.

This CF substrate (or a CF array substrate) with non-interlaced electromagnetic sensor loop also can adopt the layout for the electromagnetic sensor loops which comprise both of the first electromagnetic sensor loop and the second electromagnetic sensor loop. The first electromagnetic sensor loop and the second electromagnetic sensor loop are distributed respectively in different directions of two-dimensional Cartesian coordinates, and both of the layout for first electromagnetic sensor loop and the layout for the second electromagnetic sensor loop are layouts for the non-interlaced electromagnetic sensor loops. This integrated substrate with both of the first electromagnetic sensor loop and the second electromagnetic sensor loop and the integrated substrate 100′A showed in FIG. 6C have similar structure. The differences between this integrated substrate with both of the first electromagnetic sensor loop and the second electromagnetic sensor loop and the integrated substrate 100′A are that in this integrated substrate with both of the first electromagnetic sensor loop and the second electromagnetic sensor loop, a color filter (CF) (or a color filter array (CF array)) is deposed on the second insulation layer and several black matrixes are deposed in the CF (or a F array). Furthermore, the first electromagnetic sensor loop and the second electromagnetic sensor loop are distributed along black matrixes and deposed underneath the black matrixes. Therefore, the impact on the aperture ratio of this integrated substrate is little.

The method for fabricating the integrated substrate with both of the first electromagnetic sensor loop and the second electromagnetic sensor loop is similar to the method for fabricating the integrated substrate 100′A. In the method for fabricating the integrated substrate with both of the first electromagnetic sensor loop and the second electromagnetic sensor loop, the first electromagnetic sensor loop 104A and the second electromagnetic sensor loop 105 A as showed in FIG. 6C are fabricated and distributed on the substrate 102 by the above-mentioned method for fabricating the integrated substrate 100′A. And then, the black matrixes 118 and the CF (or the CF array) 116 are formed on the second insulation layer 112. Therefore, a CF substrate (or a CF array substrate) with both of the non-interlaced first electromagnetic sensor loop and the non-interlaced second electromagnetic sensor loop is formed and gotten by this method.

Referring to FIG. 11B, it is a cross-section view diagram illustrating an integrated substrate 200B with interlaced electromagnetic sensor loop in accordance with another embodiment of the present invention. The integrated substrate 200B is a CF substrate (or a CF array substrate). The integrated substrate 200B and the integrated substrate 100B with electromagnetic sensor loop showed in FIGS. 7A and 7B have similar structure. The differences between the integrated substrate 200B and the integrated substrate 100B are that in the integrated substrate 200B, a color filter (CF) (or a color filter array (CF array)) 116 is deposed on the first insulation layer 106 and several black matrixes 118 are deposed in the CF (or a F array) 116. Furthermore, the interlaced first electromagnetic sensor loop 104′A is distributed along black matrixes 118 and deposed underneath the black matrixes 118. Therefore, the impact on the aperture ratio of the integrated substrate 200B is little.

The method for fabricating the integrated substrate 200B is similar to the method for fabricating the integrated substrate 100B. In the method for fabricating the integrated substrate 200B, the interlaced first electromagnetic sensor loop 104′A as showed in FIG. 8E is fabricated and distributed on the substrate 102 by the above-mentioned method for fabricating the integrated substrate 100B. And then, the black matrixes 118 and the CF (or the CF array) 116 are formed on the first insulation layer 106. Therefore, a CF substrate (or a CF array substrate) with interlaced electromagnetic sensor loop is formed and gotten by this method.

Similarly, this CF substrate (or a CF array substrate) with interlaced electromagnetic sensor loop also can adopt the layout for the electromagnetic sensor loops which comprise both of the first electromagnetic sensor loop and the second electromagnetic sensor loop. The first electromagnetic sensor loop and the second electromagnetic sensor loop are distributed respectively in different directions of two-dimensional Cartesian coordinates, and both of the layout for first electromagnetic sensor loop and the layout for the second electromagnetic sensor loop are layouts for the interlaced electromagnetic sensor loops. This integrated substrate with both of the interlaced first electromagnetic sensor loop and the interlaced second electromagnetic sensor loop and the integrated substrate 100′B showed in FIG. 10B have similar structure. The differences between this integrated substrate with both of the interlaced first electromagnetic sensor loop and the interlaced second electromagnetic sensor loop and the integrated substrate 100′B are that in this integrated substrate with both of the interlaced first electromagnetic sensor loop and the interlaced second electromagnetic sensor loop, a color filter (CF) (or a color filter array (CF array)) is deposed on the second insulation layer and several black matrixes are deposed in the CF (or a F array). Furthermore, the interlaced first electromagnetic sensor loop and the interlaced second electromagnetic sensor loop are distributed along black matrixes and deposed underneath the black matrixes. Therefore, the impact on the aperture ratio of this integrated substrate caused by the interlaced first electromagnetic sensor loop and the interlaced second electromagnetic sensor loop can be reduced.

The method for fabricating the integrated substrate with both of the interlaced first electromagnetic sensor loop and the interlaced second electromagnetic sensor loop is similar to the method for fabricating the integrated substrate 100′B. In the method for fabricating the integrated substrate with both of the interlaced first electromagnetic sensor loop and the interlaced second electromagnetic sensor loop, the first electromagnetic sensor loop 104′A and the second electromagnetic sensor loop 105′ A as showed in FIG. 10A are fabricated and distributed on the substrate 102 by the above-mentioned method for fabricating the integrated substrate 100′B. And then, the black matrixes 118 and the CF (or the CF array) 116 are formed on the second insulation layer 112. Therefore, a CF substrate (or a CF array substrate) with both of the interlaced first electromagnetic sensor loop and the interlaced second electromagnetic sensor loop is formed and gotten by this method.

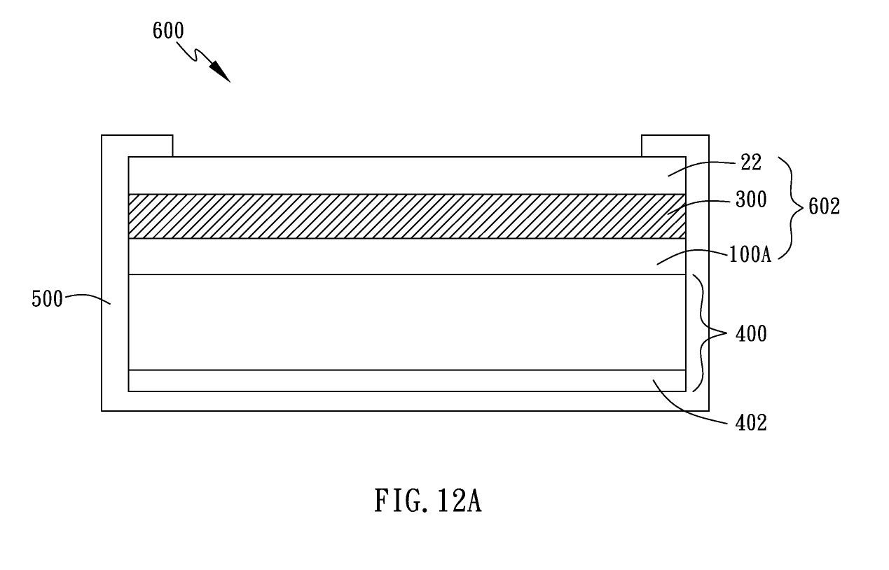

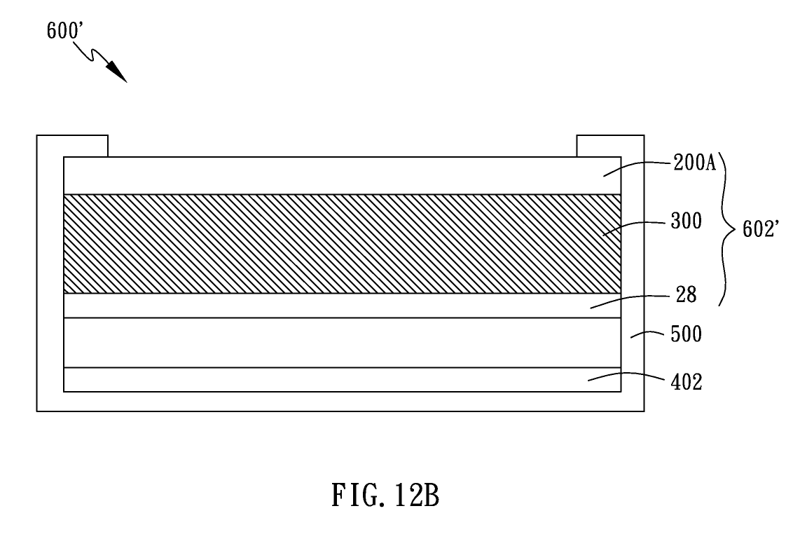

This invention further provides a display having the function of electromagnetic input and the fabricating method thereof. Referring to FIG. 12A, it is a cross-section view diagram illustrating a LCD display 600 having the function of electromagnetic input in accordance with one embodiment of the present invention. The LCD display 600 comprises a display panel 602, a backlight module 400 and a housing 500. The backlight module 400 and the LCD panel 602 are positioned and assembled in the housing 500 from bottom to top in order. A conventional CF substrate (or a conventional array CF substrate) 22 is used to be the top substrate of the LCD panel 602, and the integrated substrate 100A with electromagnetic sensor loop (as showed in FIGS. 3A and 3B) is used to be the bottom substrate of the LCD panel 602. There is a liquid crystal layer 300 filled between the top substrate 22 and the bottom substrate 100A. The backlight module 400 comprises a silicon steel 402 for reflecting electromagnetic signals emitted by an input device to enhance the electromagnetic signals detected by the electromagnetic sensor loop. A reflective layer is spread (not showed in drawings) on the silicon steel 402 so the silicon steel 402 can reflect the light and absorb the electromagnetic noise. Therefore, the silicon steel 402 can be used as both of a reflective plate of the backlight module 400 and an electromagnetic shielding of the LCD display 600.

The method for fabricating the LCD display 600 is detailed following. First, a above-mentioned integrated substrate 100A with electromagnetic sensor loop is provided or formed, and then, the integrated substrate 100A is aligned with the conventional CF substrate (or a conventional array CF substrate) 22 and the liquid crystal layer 300 is filled into the space between the integrated substrate 100A and the conventional CF substrate (or a conventional array CF substrate) 22. By this way, the LCD display panel 602 is formed. After, the backlight module 400 is positioned or assemble under the LCD display panel 602 (or on the backside of the LCD display panel 602). Therefore, the backlight module 400 and the LCD display panel 602 are positioned or assembled in the housing 500 from bottom to top in order, and the LCD display 600 having the function of electromagnetic input is formed and gotten by this method.

Besides, in other embodiments, other foregoing integrated substrates with electromagnetic sensor loop, for example the integrated substrates 100′A, 100B or 100′B, are applied to be the TFT array substrate (or the bottom substrate) of the LCD display for forming a LCD display having the function of electromagnetic input. This LCD display fabricated by the other integrated substrates 100′A, 100B or 100′B has similar structure to the LCD display 600 except the structure of the integrated substrate.

Referring to FIG. 12B, it is a cross-section view diagram illustrating a LCD display 600′ having the function of electromagnetic input in accordance with another embodiment of the present invention. The LCD display 600′ comprises a display panel 602′, a backlight module 400 and a housing 500. The backlight module 400 and the LCD panel 602′ are positioned and assembled in the housing 500 from bottom to top in order. The integrated substrate 200A with electromagnetic sensor loop (as showed in FIG. 11A) is used to be the top substrate of the LCD panel 602′, and a conventional TFT substrate (or a conventional TFT array substrate) 28 is used to be the bottom substrate of the LCD panel 602′. There is a liquid crystal layer 300 filled into the space between the top substrate 200A and the bottom substrate 28. The backlight module 400 comprises a silicon steel 402 with a reflective layer spread thereon for being used as both of a reflective plate of the backlight module 400 and for reflecting electromagnetic signals emitted by an input device and enhancing the electromagnetic signals detected by the electromagnetic sensor loop.

The method for fabricating the LCD display 600′ is the same with the method for fabricating the LCD display 600, and the only difference between the two methods is that the integrated substrate 200A with electromagnetic sensor loop (as showed in FIG. 11A) is used to be the top substrate of the LCD panel 602′ and a conventional TFT substrate (or a conventional TFT array substrate) 28 is used to be the bottom substrate of the LCD panel 602′.

Besides, in other embodiments, other foregoing integrated substrates with electromagnetic sensor loop, for example the integrated substrates 200B, the foregoing integrated substrates with both the non-interlaced first electromagnetic sensor loop and the non-interlaced second electromagnetic sensor loop or the foregoing integrated substrates with both the interlaced first electromagnetic sensor loop and the interlaced second electromagnetic sensor loop, are applied to be the CF substrate (or the top substrate) of the LCD display for forming a LCD display having the function of electromagnetic input. This LCD display fabricated by the integrated substrates 200B, the foregoing integrated substrates with both the non-interlaced first electromagnetic sensor loop and the non-interlaced second electromagnetic sensor loop or the foregoing integrated substrates with both the interlaced first electromagnetic sensor loop and the interlaced second electromagnetic sensor loop has similar structure to the LCD display 600′ except the structure of the integrated substrate.

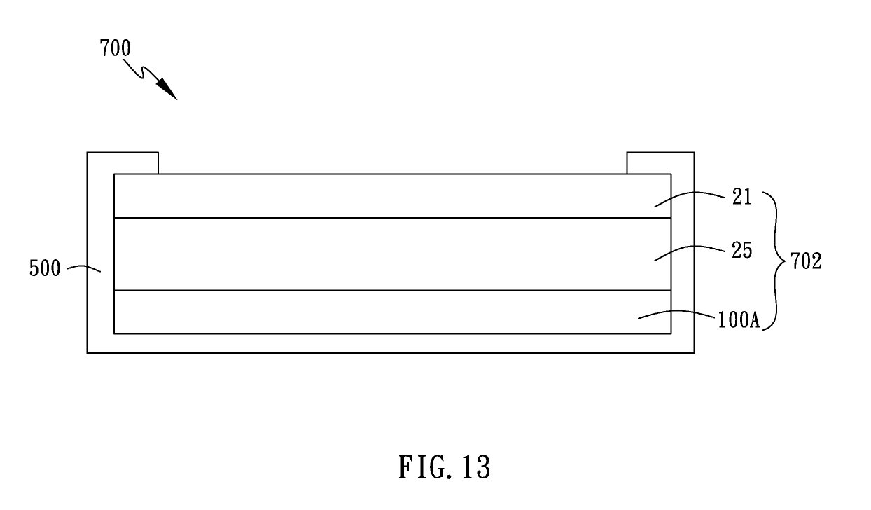

This invention further provides an OLED display or an electronic paper with electromagnetic sensor loop and the fabricating method thereof. Referring to FIG. 13, it is a cross-section view diagram illustrating the OLED/EPD display 700 having the function of electromagnetic input in accordance with one embodiment of the present invention. The OLED/EPD display 700 comprises a display panel 702 and a housing 500. The display panel 702 is placed in the housing 500. The integrated substrate 100A with electromagnetic sensor loop (as showed in FIGS. 3A and 3B) is used as the TFT substrate (or the bottom substrate) of the display panel 702, and a conventional transparent substrate is used as the top substrate 21. There is a display layer 25 deposed between the top substrate 21 and the integrated substrate 100A for forming the OLED/EPD display 700.

The method for fabricating the OLED/EPD display 700 is detailed as following. First, a above-mentioned integrated substrate 100A with electromagnetic sensor loop is provided or formed, and then, the integrated substrate 100A, the top substrate 21 and the display layer 25 are assembled to form the OLED/EPD display panel 702 having the function of electromagnetic input. The display layer 25 is deposed on the integrated substrate 100A. Therefore, the OLED/EPD display 700 having the function of electromagnetic input is formed and gotten by this method. Of course, in other embodiments, other foregoing integrated substrates with electromagnetic sensor loop, for example the integrated substrates 100′A, 100B or 100′B, are applied to fabricate the OLED/EPD display having the function of electromagnetic input. This the OLED/EPD display fabricated by the other integrated substrates 100′A, 100B or 100′B has similar structure to the OLED/EPD display 700 except the structure of the integrated substrate.

Therefore, this invention provides an integrated substrate with electromagnetic sensor loop, a display having the function of electromagnetic input and the fabricating methods thereof. In this invention, the electromagnetic sensor loop is formed directly on one substrate of a display panel for forming an integrated substrate with electromagnetic sensor loop instead of the sensor board and the tablet module of the conventional display having the function of electromagnetic input. By this way, both of the display panel and the display fabricated by this integrated substrate can have the function of electromagnetic input directly without the need of an extra sensor board and an extra tablet module. Therefore, comparing with the conventional display with electromagnetic sensor loop, the thickness, the size and the cost of the display of the present invention are substantially reduced. Furthermore, because the integrated substrate with electromagnetic sensor loop is used to be one substrate of the display panel, and there is no interference in the electromagnetic field at the edges caused by the external frame. Therefore, the electromagnetic induction at edges is not affected by the external frame and the display does not detect the position of the input device erroneously at the edges.

What is claimed is:

1. An integrated substrate with electromagnetic sensor loop, comprising:
a substrate;
at least one first electromagnetic sensor loop deposed on said substrate;
a first insulation layer deposed on said first electromagnetic sensor loop; and
an element or an element array deposed on first insulation layer for optical control or driving control.

2. The integrated substrate with electromagnetic sensor loop of claim 1, wherein said first electromagnetic sensor loop comprises:
a top side;
a bottom side opposite to said top side wherein said bottom side has a opening;
a first side respectively connected with one end of said top side and one end of said bottom side;
a second side respectively connected with another end of said top side and another end of said bottom side wherein said second side and said first side are parallel and said second side is opposite to said first side; and
a first terminal and a second terminal wherein said first terminal and said second terminal are respectively connected with two ends of said opening.

3. The integrated substrate with electromagnetic sensor loop of claim 2, wherein said top side, said bottom side, said first side, said second side, said first terminal and said second terminal are deposed on the surface of said substrate.

4. The integrated substrate with electromagnetic sensor loop of claim 2, wherein only said first side, said second side, said first terminal and said second terminal are deposed on the surface of said substrate.

5. The integrated substrate with electromagnetic sensor loop of claim 4, further comprising a first protective layer deposed on said first side, said second side, said first terminal, said second terminal and the surface of said substrate.

6. The integrated substrate with electromagnetic sensor loop of claim 5, further comprising a plurality of through holes passing through said first protective layer wherein said through holes are deposed at the two ends of said first side, the two ends of said second side, one end of said first terminal and one end of said second terminal respectively.

7. The integrated substrate with electromagnetic sensor loop of claim 6, wherein a metal or a conductive material is filled into said through holes to form conductors passing through said first protective layer, and said conductors are electrically connected with the two ends of said first side, the two ends of said second side, one end of said first terminal and one end of said second terminal respectively.

8. The integrated substrate with electromagnetic sensor loop of claim 7, wherein said top side and said bottom side are deposed on said first protective layer and said conductors are electrically connected with the two ends of said top side and the two ends of said bottom side respectively.

9. The integrated substrate with electromagnetic sensor loop of claim 2, wherein said first insulation layer is distributed in the one direction of two-dimensional coordinates.

10. The integrated substrate with electromagnetic sensor loop of claim 9, further comprising a second electromagnetic sensor loop deposed on said first protective layer wherein said second electromagnetic sensor loop is distributed in the another direction of two-dimensional coordinates and said second electromagnetic sensor loop has the same structure with said first electromagnetic sensor loop.

11. The integrated substrate with electromagnetic sensor loop of claim 10, further comprising a second insulation layer deposed on said first insulation layer for covering said second electromagnetic sensor loop.

12. The integrated substrate with electromagnetic sensor loop of claim 11, wherein said element or said element array are depose on said second insulation.

13. The integrated substrate with electromagnetic sensor loop of claim 1, wherein said element or said element array is a thin-film transistor (TFT) or a thin-film transistor array (TFT array), and said substrate is a TFT substrate or a TFT array substrate.

14. The integrated substrate with electromagnetic sensor loop of claim 1, wherein said element or said element array is a color filter (CF) or a color filter array (CF array), and said substrate is a CF substrate or a CF array substrate.

15. A display with electromagnetic sensor loop, comprising:
a display panel for displaying images wherein said display panel has an integrated substrate with electromagnetic sensor loop and said integrated substrate comprises:
a substrate;
at least one first electromagnetic sensor loop deposed on said substrate;
a first insulation layer deposed on said first electromagnetic sensor loop; and
an element or an element array deposed on first insulation layer for optical control or driving control.

16. The display with electromagnetic sensor loop of claim 15, wherein said first electromagnetic sensor loop comprises:
a top side;
a bottom side opposite to said top side wherein said bottom side has a opening;
a first side respectively connected with one end of said top side and one end of said bottom side;
a second side respectively connected with another end of said top side and another end of said bottom side wherein said second side and said first side are parallel and said second side is opposite to said first side; and
a first terminal and a second terminal wherein said first terminal and said second terminal are respectively connected with two ends of said opening.

17. The display with electromagnetic sensor loop of claim 16, wherein said top side, said bottom side, said first side, said second side, said first terminal and said second terminal are deposed on the surface of said substrate.

18. The display with electromagnetic sensor loop of claim 16, wherein only said first side, said second side, said first terminal and said second terminal are deposed on the surface of said substrate.

19. The display with electromagnetic sensor loop of claim 18, further comprising a first protective layer deposed on said first side, said second side, said first terminal, said second terminal and the surface of said substrate.

20. The display with electromagnetic sensor loop of claim 19, further comprising a plurality of through holes passing through said first protective layer wherein said through holes are deposed at the two ends of said first side, the two ends of said second side, one end of said first terminal and one end of said second terminal respectively.

21. The display with electromagnetic sensor loop of claim 20, wherein a metal or a conductive material is filled into said through holes to form conductors passing through said first protective layer, and said conductors are electrically connected with the two ends of said first side, the two ends of said second side, one end of said first terminal and one end of said second terminal respectively.

22. The display with electromagnetic sensor loop of claim 21, wherein said top side and said bottom side are deposed on said first protective layer and said conductors are electrically connected with the two ends of said top side and the two ends of said bottom side respectively.

23. The display with electromagnetic sensor loop of claim 16, wherein said first insulation layer is distributed in the one direction of two-dimensional coordinates.

24. The display with electromagnetic sensor loop of claim 23, further comprising a second electromagnetic sensor loop deposed on said first protective layer wherein said second electromagnetic sensor loop is distributed in the another direction of two-dimensional coordinates and said second electromagnetic sensor loop has the same structure with said first electromagnetic sensor loop.

25. The display with electromagnetic sensor loop of claim 24, further comprising a second insulation layer deposed on said first insulation layer for covering said second electromagnetic sensor loop.

26. The display with electromagnetic sensor loop of claim 25, wherein said element or said element array are depose on said second insulation.

27. The display with electromagnetic sensor loop of claim 15, wherein said element or said element array is a thin-film transistor (TFT) or a thin-film transistor array (TFT array), and said substrate is a TFT substrate or a TFT array substrate.

28. The display with electromagnetic sensor loop of claim 27, wherein said display panel is LCD panel and said display panel comprises:
a top substrate wherein said top substrate is a CF substrate;
a bottom substrate wherein said bottom substrate is said integrated substrate with electromagnetic sensor loop; and
a liquid crystal layer filled between said CF substrate and said integrated substrate.

29. The display with electromagnetic sensor loop of claim 28, further comprising a backlight module for providing a light source.

30. The display with electromagnetic sensor loop of claim 29, wherein said backlight module comprises a silicon steel for reflecting electromagnetic signals emitted by an input device to enhance the electromagnetic signals detected by said first electromagnetic sensor loop.

31. The display with electromagnetic sensor loop of claim 30, wherein a reflective layer is spread on said silicon steel to be a reflective plate of said backlight module.

32. The display with electromagnetic sensor loop of claim 27, wherein said display panel is an electronic paper display panel (EPD panel) or an organic light emitting diode display panel (OLED panel).

33. The display with electromagnetic sensor loop of claim 32, wherein said display panel comprises:
a top substrate;
a bottom substrate wherein said bottom substrate is said integrated substrate with electromagnetic sensor loop; and
a display layer deposed between said top substrate and said integrated substrate;

34. The display with electromagnetic sensor loop of claim 15, wherein said element or said element array is a color filter (CF) or a color filter array (CF array), and said substrate is a CF substrate or a CF array substrate.

35. The display with electromagnetic sensor loop of claim 34, wherein said display panel is LCD panel and said display panel comprises:
a top substrate wherein said top substrate is said integrated substrate with electromagnetic sensor loop;
a bottom substrate wherein said bottom substrate is a is a TFT substrate or a TFT array substrate; and
a liquid crystal layer filled between said integrated substrate and said TFT substrate/TFT array substrate.
